(19) United States
(12) Patent Application Publication
(10) Pub. No.: US 2013/0126866 A1
(43) Pub. Date: May 23, 2013

(54) SEMICONDUCTOR DEVICE AND MANUFACTURING METHOD THEREOF

(71) Applicant: Sumitomo Electric Industries, Ltd., Osaka-shi (JP)

(72) Inventor: Satoshi HATSUKAWA, Osaka-shi (JP)

(73) Assignee: SUMITOMO ELECTRIC INDUSTRIES, LTD., Osaka-shi (JP)

(21) Appl. No.: 13/661,538

(22) Filed: Oct. 26, 2012

Related U.S. Application Data
(60) Provisional application No. 61/562,757, filed on Nov. 22, 2011.

(30) Foreign Application Priority Data
Nov. 22, 2011 (JP) 2011-255264

(51) Int. Cl. H01L 23/48; H01L 21/66

(52) U.S. Cl. 257/48; 438/12; 257/E21.524; 257/E21.526; 257/E23.01

(57) ABSTRACT

A semiconductor device in one embodiment includes a wiring board having a wiring pattern; an N semiconductor elements(where N denotes a natural number equal to or greater than 2) mounted on a wiring board; and a current detection parts for detecting a current flowing through m semiconductor elements (where m denotes a natural number equal to or greater than 1 but less than M) of M semiconductor elements(where M denotes a natural number equal to or greater than 1 but equal to or less than N) mounted on the wiring board and selected from the N semiconductor elements. The M semiconductor elements are electrically connected in parallel through the wiring pattern, and the m semiconductor elements are electrically connected in parallel to the other semiconductor elements of the M semiconductor elements through the current detection part.

### CROSS-REFERENCE RELATED APPLICATIONS

This application claims priority to Provisional Application Ser. No. 61/562757 filed on Nov. 22, 2011 and claims the benefit of Japanese Patent Application No. 2011-255264, filed on Nov. 22, 2011, all of which are incorporated herein by reference in their entirety.

### BACKGROUND

1. Field

The embodiments of present invention relate to a semiconductor device and a manufacturing method thereof.

2. Description of the Related Art

With a semiconductor device in which a plurality of semiconductor elements is med on a wiring board, a shunt resistor which functions as a current detection part for detecting the current flowing through the semiconductor elements is provided, as disclosed in, for example, Non-patent Document 1 (Manabu Watanabe, Taku Sato, and Yoshinori Oda, “Intelligent Power Module with a Built-in Current Sensor”, FUJI ELECTRIC JOURNAL, 1999 March, Vol. 72-No. 3, pp. 203-207). The current which is detected by such a current detection part can be utilized for controlling of, for example, a protection circuit for a semiconductor device.

Further, as an example of semiconductor device having a plurality of semiconductor elements, a semiconductor device in which a plurality of semiconductor elements 100, such as transistors, are connected in parallel as shown in FIG. 9 is known. This trend can be seen especially with semiconductor devices including semiconductor elements which utilize a wide bandgap semiconductor, such as SiC. The cause is this: since the semiconductor devices including semiconductor elements which utilize a wide bandgap semiconductor are used for power handling, or the like, they are required to accommodate a large current. However, the semiconductor elements which utilize a wide bandgap semiconductor, such as SiC or GaN, have not been large-sized as with the conventional ones which utilize Si, and each semiconductor element cannot accommodate a large current. Therefore, they must be connected in parallel to ensure a predetermined current capacity.

### SUMMARY

Semiconductor devices having a configuration in which a plurality of semiconductor elements is connected in parallel as shown in FIG. 9 are generally inspected for the semiconductor elements after the plurality of semiconductor elements having been disposed on a wiring board, and provided with a predetermined wiring. Then, the wiring of the semiconductor elements other than those which have passed the inspection is cut. In other words, after the plurality of semiconductor elements wired on a wiring board having been inspected, the no-good semiconductor elements are excluded from the parallel connection.

In a case where such a semiconductor device is to be equipped with a shunt resistor (a current detection part) for detecting a current flowing through the semiconductor elements as described above, it is considered to dispose the shunt resistor such that the currents flowing through the plurality of semiconductor elements is collectively passed through the shunt resistor, on the presumption that the no-good semiconductor elements are excluded from the parallel connection. In other words, as shown in FIG. 9, it is considered to connect shunt resistors 110A and 110B in series with wirings which connect first and second main terminals of the plurality of semiconductor elements 100, respectively.

However, in this case, there has been a tendency of the loss in the current detection part, such as a shunt resistor, being increased.

Then, it is an object of the present invention to provide a semiconductor device which includes a plurality of semiconductor elements and can reduce the loss in detecting the current flowing through the semiconductor elements, and a manufacturing method thereof.

A semiconductor device according to one aspect of the present invention includes a wiring board having a wiring pattern; N semiconductor elements (where N denotes a natural number equal to or greater than 2) mounted on the wiring board; and a current detection part for detecting a current flowing through m semiconductor elements (where m denotes a natural number equal to or greater than 1 but less than M) of the M semiconductor elements (where M denotes a natural number equal to or greater than 1 but equal to or less than N) mounted on the wiring board and selected from the N semiconductor elements. The M semiconductor elements are electrically connected in parallel through the wiring pattern, and the m semiconductor elements are electrically connected in parallel to the other semiconductor elements of the M semiconductor elements through the current detection part.

With this configuration, the M semiconductor elements are connected in parallel, whereby the M semiconductor elements can be utilized for passing a larger current. Then, since the m semiconductor elements of the M semiconductor elements are utilized for detecting the current flowing through the semiconductor elements, the loss in detecting the current flowing through the semiconductor elements can be reduced.

In one embodiment, the M semiconductor elements may be semiconductor elements which, after the N semiconductor elements having been wired on the wiring pattern such that each of the semiconductor elements is drivable, have been judged as good in an inspection for judging whether the semiconductor elements are good or no-good. In this case, the (N-M) semiconductor elements other than the M semiconductor elements of the N semiconductor elements are electrically separated from the M semiconductor elements.

In this way, the semiconductor elements which have been judged as good in the inspection are connected in parallel, and electrically separated from the other (N-M) semiconductor elements, whereby the semiconductor device can be reliably driven.

In one embodiment, m may be 1. In this case, the current detection part detects the current flowing through a single semiconductor element, whereby the loss in detecting the current can be further reduced.

In one embodiment, the aforementioned semiconductor element has first and second main terminals, and a control terminal which receives a control signal for controlling the conduction between the first and second main terminals, and the N semiconductor elements may be physically disposed in parallel. In this mode, the wiring pattern may have N first wiring regions which are separated from each other and provided in correspondence to the first main terminal of each of the N semiconductor elements; N second wiring regions which are separated from each other and provided in correspondence to the second main terminal of each of the N semiconductor elements; and a third wiring region to which the control terminals of the N semiconductor elements are connected. In this case, the first and second main terminals and the control terminals of the M semiconductor elements may be electrically connected to the corresponding first to third wiring regions, respectively. The semiconductor element for current detection as a semiconductor element the current for which is detected by the current detection part may be a semiconductor element located at the extreme end of the M semiconductor elements which are disposed in parallel. In this case, at least one of a couple of the first wiring region corresponding to the semiconductor element for current detection and the first wiring region corresponding to the semiconductor element adjacent to the semiconductor element for current detection, and a couple of the second wiring region corresponding to the semiconductor element for current detection and the second wiring region corresponding to the semiconductor element adjacent to the semiconductor element for current detection may be connected through the semiconductor element for current detection. In this case, of the couples of the first wiring regions corresponding to the semiconductor elements adjacent to each other in the N first wiring regions and of the couples of the second wiring regions corresponding to the semiconductor elements adjacent to each other in the N second wiring regions, the couples other than the couple connected by the current detection part may be connected with a conductor wire. In this mode, the (N-M) semiconductor elements other than the M semiconductor elements of the N semiconductor elements may be electrically separated from the M semiconductor elements.

In this case, for the first and second main terminals and the control terminals of the N semiconductor elements, the first to third wiring regions are provided, whereby, for example, after the N semiconductor elements having been mounted on the wiring board, whether the respective semiconductor elements are good or no-good can be individually inspected. In addition, since, for the first and second main terminals and the control terminals of the N semiconductor elements, the first to third wiring regions are provided, parallel connection of the M semiconductor elements can be easily performed. Further, the M semiconductor elements are electrically connected in parallel, using the corresponding first to third wiring regions. Then, to the first and second wiring regions which correspond to the semiconductor element for current detection and the semiconductor element adjacent thereto, respectively, the current detection part is connected as described above; in the N first and second wiring regions, the couples of adjacent first wiring regions and the couples of adjacent second wiring regions other than the couple connected by the current detection part are connected with the conductor wire; and the (N-M) semiconductor elements other than the M semiconductor elements of the N semiconductor elements are electrically separated from the M semiconductor elements. Thereby, there is no need for further securing at least one of the wiring region for arranging and connecting the M semiconductor elements and the wiring region for connecting the current detection part, whereby the wiring board can be made smaller. As a result, the semiconductor device can be made compact. In addition, the current detection part detects the current flowing through a single semiconductor element, whereby the loss in detecting the current can be further reduced.

In one embodiment, a semiconductor material forming the semiconductor element may be SiC, GaN or diamond. Semiconductor devices provided with semiconductor elements containing such a semiconductor material have been utilized for power handling, allowing a larger current to be passed through the semiconductor devices, while the size of the semiconductor elements is small, as compared to that of the semiconductor elements containing Si, or the like. Therefore, it is necessary to connect the semiconductor elements in parallel for ensuring the current capacity, and thus the aforementioned scheme which reduces the loss in detection of the current flowing through the semiconductor elements will provide a more advantageous scheme for semiconductor devices including semiconductor elements having SiC, GaN or diamond as a semiconductor material.

Another aspect of the present invention also relates to a manufacturing method of semiconductor device, including the steps of: mounting N semiconductor elements (where N denotes a natural number equal to or greater than 2) on a wiring board having a wiring pattern; and electrically connecting of the M semiconductor elements (where M denotes a natural number equal to or greater than 1 but equal to or less than N) selected from the N semiconductor elements in parallel through the wiring pattern. In the parallel connection step of this manufacturing method, the m semiconductor elements (where m denotes a natural number equal to or greater than 1 but less than M) of the M semiconductor elements are connected in parallel to the other semiconductor elements of the M semiconductor devices through a current detection part for detecting a current flowing through the m semiconductor elements.

With such a manufacturing method, it is possible to manufacture a semiconductor device in which the M semiconductor elements are connected in parallel, and the m semiconductor elements can be utilized for detecting the current flowing through the semiconductor elements. With such a semiconductor device, the M semiconductor elements can be utilized for passing a larger current. In addition, the loss in detecting the current flowing through the semiconductor elements can be reduced, when compared to that in detecting the current flowing through all the M semiconductor elements.

In one embodiment, the aforementioned manufacturing method may further include the steps of: drivably wiring of the N semiconductor elements mounted on the wiring pattern in the mounting step; inspecting whether the semiconductor elements are good or no-good by driving the N semiconductor elements; and cutting at least a part of wiring between the (N-M) semiconductor elements and the wiring pattern such that the (N-M) semiconductor elements which have been judged as no-good in the inspection will not be driven. In the parallel connection step in this mode, the M semiconductor elements selected from the N semiconductor elements as semiconductor elements which have been judged as good in the inspection may be electrically connected in parallel through the wiring pattern.

In this case, a semiconductor device in which the semiconductor elements which have been judged as good in the inspection are connected in parallel, while the other (N-M) semiconductor elements will not be driven can be manufactured. Therefore, the semiconductor device manufactured can be reliably driven.

In one embodiment of the aforementioned manufacturing method, m may be 1. In this case, with the semiconductor device manufactured, the current flowing through a single semiconductor element may be detected, whereby the loss due to the detection of the current flowing through the semiconductor elements can be further reduced.

In one embodiment, the aforementioned manufacturing method may further include the steps of: drivably wiring the N semiconductor elements mounted on the wiring pattern in the mounting step, respectively; inspecting whether the semiconductor elements are good or no-good by driving the N semiconductor elements; and cutting at least a part of wiring between the (N-M) semiconductor elements and the wiring pattern such that the (N-M) semiconductor elements which have been judged as no-good in the inspection will not be driven. In this mode, in the aforementioned mounting step, the N semiconductor elements may be physically disposed in parallel to be mounted on the wiring board. In addition, the m may be 1, and the semiconductor element for current detection as a semiconductor element the current for which is detected by the current detection part may be a semiconductor element located at the extreme end of the M semiconductor elements. Further, the semiconductor element may have first and second main terminals, and a control terminal which receives a control signal for controlling the conduction between the first and second main terminals. In addition, the wiring pattern may have: N first wiring regions which are separated from each other and provided in correspondence to the first main terminal of each of the N semiconductor elements; N second wiring regions which are separated from each other and provided in correspondence to the second main terminal of each of the N semiconductor elements; and a third wiring region to which the control terminals of the N semiconductor elements are electrically connected. In the aforementioned wiring step, the first and second main terminals and the control terminals of the N semiconductor element may be electrically connected to the corresponding first to third wiring regions, respectively. Further, in the cutting step, electrical connection between at least one of the first and second main terminals and the control terminals of the (N-M) semiconductor elements other than the M semiconductor elements of the N semiconductor elements and the corresponding first to third wiring regions may be cut. Further, in the parallel connection step, at least one of a couple of the first wiring region corresponding to the semiconductor element for current detection and the first wiring region corresponding to the semiconductor element adjacent to the semiconductor element for current detection, and a couple of the second wiring region corresponding to the semiconductor element for current detection and the second wiring region corresponding to the semiconductor element adjacent to the semiconductor element for current detection may be connected through the semiconductor element for current detection, and of the couples of the first wiring regions corresponding to the semiconductor elements adjacent to each other in the N first wiring regions and of the couples of the second wiring regions corresponding to the semiconductor elements adjacent to each other in the N second wiring regions, the couples other than the couple connected by the current detection part may be connected with a conductor wire.

In this case, a semiconductor device in which the semiconductor elements which have been judged as good in the inspection are connected in parallel, and a semiconductor device electrically separated from the other (N-M) semiconductor elements can be manufactured. Therefore, the semiconductor device manufactured can be reliably driven. The first and second main terminals and the control terminals of the M semiconductor elements are electrically connected to the corresponding first to third wiring regions, respectively, whereby, in the inspection step, whether the respective semiconductor elements are good or no-good can be individually inspected. Further, the M semiconductor elements are electrically connected in parallel, using the corresponding first to third wiring regions. Then, to the first and second wiring regions which correspond to the semiconductor element for current detection and the semiconductor element adjacent thereto, respectively, the current detection part is connected as described above, and in the N first and second wiring regions, the couples of adjacent first wiring regions and the couples of adjacent second wiring regions other than the couple connected by the current detection part are connected with the conductor wire. Thereby, there is no need for further securing at least one of the wiring region for arranging and connecting the M semiconductor elements and the wiring region for connecting the current detection part. Therefore, the wiring board can be made smaller, whereby the semiconductor device can be made compact. In addition, the current detection part detects the current flowing through a single semiconductor element, whereby the loss in detecting the current can be further reduced.

As mentioned above, a semiconductor device which includes a plurality of semiconductor elements, and can reduce the loss in detecting the current flowing through the semiconductor elements, and a manufacturing method thereof can be provided.

### BRIEF DESCRIPTION OF THE DRAWINGS

FIG. 1 is a drawing schematically showing a configuration of a semiconductor device according to one embodiment of the present invention;

FIG. 2 is a drawing schematically showing a sectional configuration along the II-II line in FIG. 1;

FIG. 3 is a drawing showing a circuit configuration of the semiconductor device shown in FIG. 1;

FIG. 4 is a flowchart giving one example of manufacturing method of the semiconductor device shown in FIG. 1;

FIG. 5 is a drawing showing a state of a wiring board after the wiring step given in FIG. 4 having been implemented;

FIG. 6 is a drawing showing a state of the wiring board after the cutting step in FIG. 4 having been implemented;

FIG. 7 is a drawing schematically showing a configuration of a semiconductor device according to another embodiment of the present invention;

FIG. 8 is a drawing schematically showing a configuration of a semiconductor device according to still another embodiment of the present invention; and

FIG. 9 is a drawing showing an example of circuit configuration in a case where the full current flowing through a plurality of semiconductor elements is detected with shunt resistors.

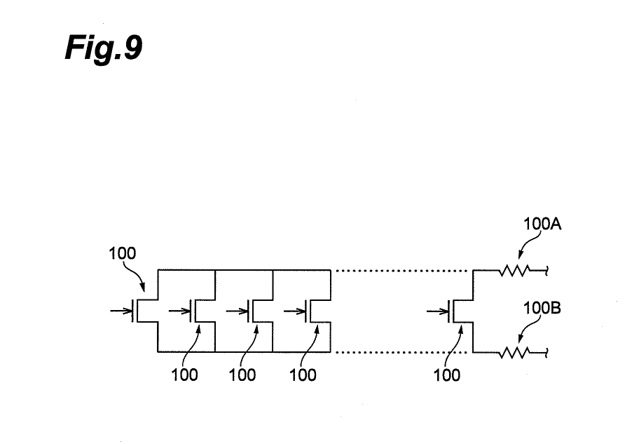

### DETAILED DESCRIPTION

Hereinbelow, with reference to the drawings, embodiments of the present invention will be explained. In explanation of the drawings, the same element will be provided with the same numeral, and the duplicative explanation will be omitted. The ratio in size as given in a drawing is not necessarily agree with that in the explanation. In the explanation, a word indicating a particular direction, such as “upper”, “lower”, or the like, is a word of expedient based on the state shown in the drawing.

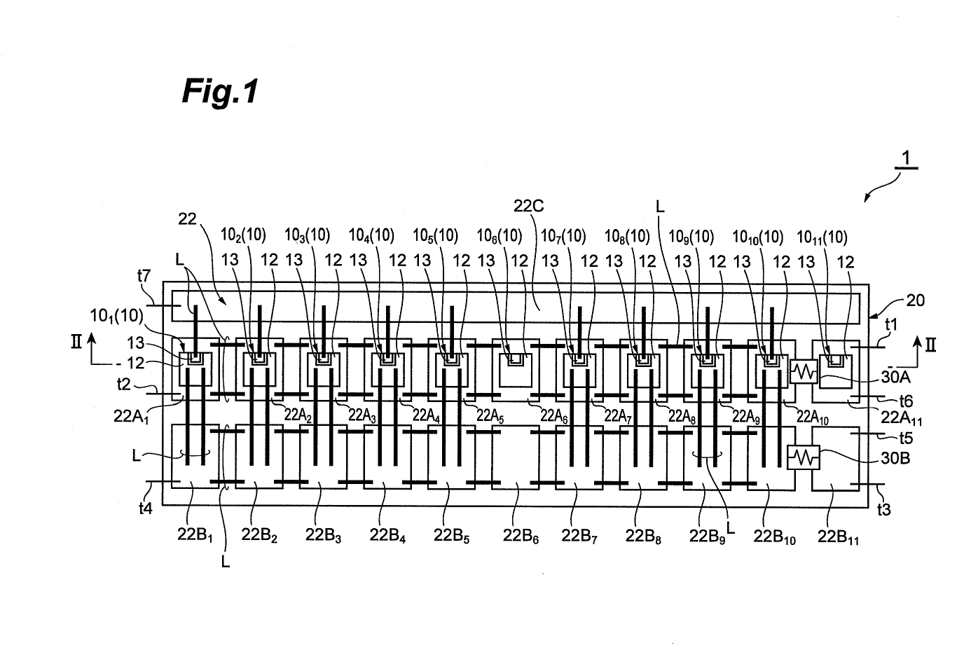

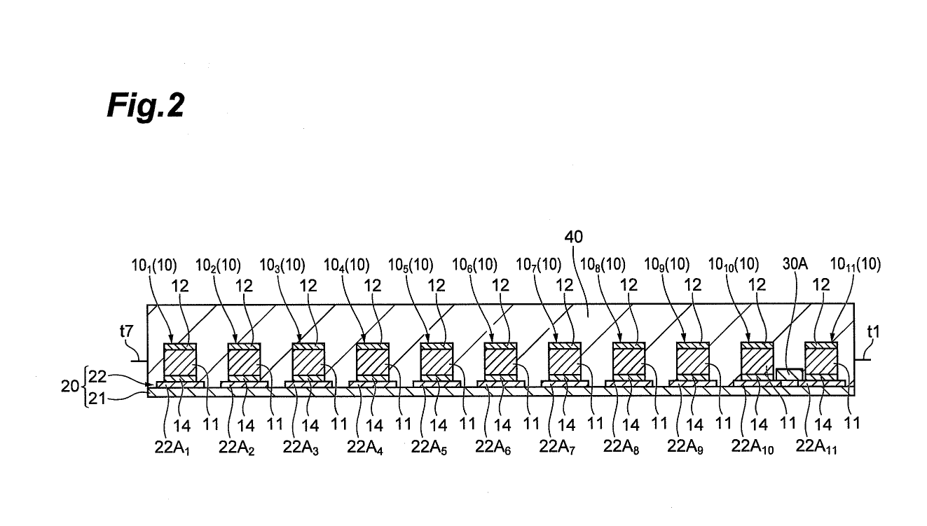

FIG. 1 is a drawing schematically showing a configuration of a semiconductor device according to one embodiment. FIG. 1 schematically shows the configuration when the semiconductor device is viewed from a side on which semiconductor elements are mounted. FIG. 2 is a drawing schematically showing a sectional configuration along the II-II line in FIG. 1.

The semiconductor device 1 includes N semiconductor elements 10 (where N denotes a natural number equal to or greater than 1), a wiring board 20 on which the N semiconductor elements 10 are mounted, and shunt resistors 30A and 30B as a current detection part for detecting the current flowing through the semiconductor element 10. In one embodiment, for protection and moisture proofing of the N semiconductor elements 10, the semiconductor device 1 may be molded with resin 40 such that the N semiconductor elements 10 are sealed as shown in FIG. 2. In FIG. 1, in order to show the configuration of the wiring board 20, the resin 40 is omitted. In FIGS. 1 and 2, the shunt resistors 30A and 30B are schematically shown.

The semiconductor element 10 is a vertical insulated field-effect transistor (MOSFET: Metal-Oxide-Semiconductor Field-Effect Transistor). The semiconductor element 10 is configured by an FET structure part 11 which is formed to contain a wide bandgap semiconductor, such as SiC, GaN or diamond, having an FET structure as an MOSFET; a source terminal part 12 and a gate terminal part 13 which are provided on a front surface of the FET structure part 11; and a drain terminal part 14 which is provided on a back surface of the FET structure part 11. The respective components of the semiconductor element 10 may have any configuration, provided that the semiconductor element 10 functions as a vertical MOSFET. Therefore, the detailed explanation of the respective components will be omitted. The shape of the semiconductor element 10 is, for example, a square or rectangle in plan view. The length of one side of the semiconductor element 10 is, for example, approximately 2 or 3 mm. In a case where the shape of the semiconductor element 10 is a rectangle in plan view, the length of the longer side may be approximately 2 or 3 mm.

The number of all semiconductor elements 10 which are mounted on the wiring board 20 may be any number, provided that a predetermined current capacity as the semiconductor device 1 can be secured, even in a case where, upon implementing a plurality of semiconductor elements 10 on the wiring board 20 in the manufacturing process of the semiconductor device 1, some semiconductor elements 10 of those semiconductor elements 10 have become no-good. In the present specification, it is assumed that, of the N semiconductor elements 10, M semiconductor elements 10 (where M denotes a natural number equal to or greater than 1 but equal to or less than N) are good, in other words, normally functioning semiconductor elements 10, and (N-M) semiconductor elements 10 are no-good semiconductor elements 10.

The wiring board 20 has an insulating substrate 21, and a wiring pattern 22 formed of a metal, such as copper, on the insulating substrate 21. The wiring pattern 22 may be formed by, for example, printing on the insulating substrate 21.

In the semiconductor device 1, the M semiconductor elements 10 are electrically connected in parallel through the wiring pattern 22. In this parallel connection, one semiconductor element 10 of the M semiconductor elements 10 is connected in parallel to the other semiconductor elements 10 of the M semiconductor elements 10 through the shunt resistors 30A and 30B.

Hereinbelow, the configuration of the semiconductor device 1 will be specifically explained. For convenience of explanation, in the following, as shown in FIGS. 1 and 2, a mode in which eleven semiconductor elements 10 are mounted on the wiring board 20 will be explained. In a case where, in the explanation of the mode including the eleven semiconductor elements 10, it is required to distinguish among the eleven semiconductor elements 10, the eleven semiconductor elements 10 will be referred to as the semiconductor elements 10₁ to 10₁₁. Also for the components of the semiconductor device 1 that are provided in correspondence to the respective semiconductor elements 10₁ to 10₁₁, in a case where it is required to distinguish among them for explanation, the like notation will be adopted. In the semiconductor device 1 shown in FIGS. 1 and 2, the semiconductor elements 10₆ and 10₁₁ are no-good semiconductor elements, and the remaining nine semiconductor elements 10₁ to 10₅, and 10₇ to 10₁₀ semiconductor elements are those which normally function. In other words, in the following explanation, M=9.

The wiring pattern 22 which the wiring board 20 has include eleven drain electrode regions (first wiring regions) 22A₁ to 22A₁₁, eleven source electrode regions (second wiring regions) 22B₁ to 22B₁₁, and one gate electrode region (a third wiring region).

The drain electrode regions 22A₁ to 22A₁₁ are disposed in parallel, being physically separated from one another. The source electrode regions 22B₁ to 22B₁₁ are disposed in correspondence to the drain electrode regions 22A₁ to 22A₁₁, respectively. The gate electrode region 22C extends in the direction of arrangement of the drain electrode regions 22A₁ to 22A₁₁.

In the respective drain electrode regions 22A₁ to 22A₁₁, the corresponding semiconductor element 10₁, 10₂, . . . , or 10₁₁ is mounted. Each of the semiconductor elements 10₁ to 10₁₁ is mounted on the drain electrode region 22A₁, 22A₂, . . . , or 22A₁₁ such that the drain terminal part 14 thereof is located on the side of the drain electrode region 22A₁, 22A₂, . . . , or 22A₁₁. The respective semiconductor elements 10₁ to 10₁₁ are die-bonded to the corresponding drain electrode region 22A₁, 22A₂, . . . , or 22A₁₁ by utilizing, for example, a solder. Accordingly, the drain terminal part 14 of the respective semiconductor elements 10₁ to 10₁₁ is electrically connected to the corresponding drain electrode region 22A₁, 22A₂, . . . , or 22A₁₁. The size of the shape of the respective drain electrode regions 22A₁ to 22A₁₁ in plan view may be any size, provided that it is larger than the size of the corresponding semiconductor element 10₁, 10₂, . . . , or 10₁₁ such that the semiconductor element 10₁, 10₂, . . . , or 10₁₁ can be disposed thereon, and that it allows the respective drain electrode regions 22A₁ to 22A₁₁ to be disposed separately from one another on the wiring board 20.

The respective source electrode regions 22B₁ to 22B₁₁ are regions to which the source terminal part 12 of the corresponding semiconductor elements 10₁ to 10₁₁ is electrically connected through a conductor wire L (shown with a bold solid line FIG. 1). The electrical connection utilizing the conductor wire L may be referred to as the wire bonding. The gate electrode region 22C is a region to which the gate terminal parts 13 of the eleven semiconductor elements 10₁ to 10₁₁ are electrically connected through the conductor wires L, such as a wire. In the present embodiment, a single gate electrode region 22C is provided for the semiconductor elements 10₁ to 10₁₁.

In a case where, as in the present embodiment, the two no-good semiconductor elements 10₆ and 10₁₁ are included, the electrical connection across the no-good semiconductor elements 10₆ and 10₁₁ and the corresponding source electrode regions 22B₆ and 22B₁₁, and across the no-good semiconductor elements 10₆ and 10₁₁ and the gate electrode regions 22C are cut, respectively.

The shunt resistors 30A and 30B are provided on the wiring board 20 so as to detect the current flowing through the extreme end semiconductor element 10₁₀ of the normally functioning nine semiconductor elements 10₁ to 10₅, and 10₇ to 10₁₀ of the eleven semiconductor elements 10₁ to 10₁₁ physically disposed in parallel. Specifically, one end of the shunt resistor 30B is connected to the source electrode region 22B₁₀, while the other end of the shunt resistor 30B is connected to the source electrode region 22B_{11.} Likewise, one end of the shunt resistor 30A is connected to the drain electrode region 22A₁₀, while the other end of the shunt resistor 30A is connected to the drain electrode region 22A₁₁. Thereby, one end of the shunt resistors 30B and 30A is electrically connected to the source terminal part 12 and the drain terminal part 14 of the semiconductor element 10₁₀, respectively.

Of the couples of adjacent source electrode regions, 22B₁ and 22B₂, 22B₂ and 22B₃, 22B₁₀ and 22B₁₁, the couples of adjacent source electrode regions other than the couple of source electrode regions 22B₁₀ and 22B₁₁, which are connected by the shunt resistor 30B, are connected with the conductor wires L. Likewise, of the adjacent drain electrode regions 22A₁ to 22A₁₁, the couples of the adjacent drain electrode regions other than the couple of the drain electrode regions 22A₁₀ and 22A₁₁ which are connected by the shunt resistor 30A are connected with the conductor wires L.

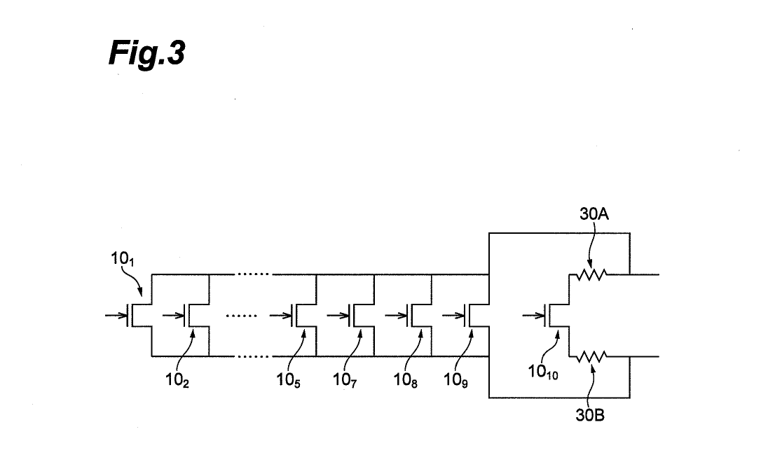

FIG. 3 is a circuit diagram showing a wiring structure of the normally functioning semiconductor elements 10 of the semiconductor elements 10 which the semiconductor device 1 has. As shown in FIG. 3, the normally functioning semiconductor elements 10₁ to 10₅, and 10₇ to 10₁₀ are electrically connected in parallel. Of the semiconductor elements 10₁ to 10₅ and 10₇ to 10₁₀, the semiconductor element 10₁₀ is connected in parallel to the other semiconductor elements 10₁ to 10₅ and 10₇ to 10₉ through the shunt resistors 30A and 30B. Therefore, by measuring the voltage across the shunt resistor 30B or 30A, the current flowing through the semiconductor element 10₁₀ on the source side or the drain side can be detected, respectively.

In one embodiment, as schematically shown in FIG. 1, the semiconductor device 1 may have measuring terminals t1 and t2 for measuring the voltage across the shunt resistor 30A. One end of the measuring terminal t1 is connected to the drain electrode region 22A₁₁, while one end of the measuring terminal t2 is connected to the other drain electrode region 22A₁. The semiconductor device 1 may have measuring terminals t3 and t4 for measuring the voltage across the shunt resistor 30B. One end of the measuring terminal t3 is connected to the source electrode region 22B₁₁, while one end of the measuring terminal t4 is connected to the source electrode region 22B₁. In addition, the semiconductor device 1 has external connection terminals t5 and t6 for supplying a voltage to the source terminal parts 12 and the drain terminal parts 14 of the semiconductor elements 10₁ to 10₅ and 10₇ to 10₁₀. One end of the external connection terminal t5 and that of the external connection terminal t6 may be connected to any one of the source electrode regions 22B₁ to 22B₁₁ and any one of the drain electrode regions 22A₁ to 22A₁₁, respectively. In FIG. 1, one end of the external connection terminal t5 and that of the external connection terminal t6 are connected to the source electrode region B₁₁ and the drain electrode region A₁₁, respectively. In addition, the semiconductor device 1 may have an external connection terminal t7 for supplying a control signal to the gate terminal parts 13 of the semiconductor elements 10₁ to 10₅ and 10₇ to 10₁₀. One end of the external connection terminal t7 may be connected to the gate electrode region 22C. In a case where, as exemplified in FIG. 2, the semiconductor elements 10₁ to 10₁₁ are molded with the resin 40, the other ends of the measuring terminals t1 to t4 and those of the external connection terminals t5 to t7 may be protruded from the resin 40 to the outside so as to be externally connected. Note that, in FIGS. 1 and 2, the measuring terminals t1 to t4 and the external connection terminals t5 to t7 are schematically shown.

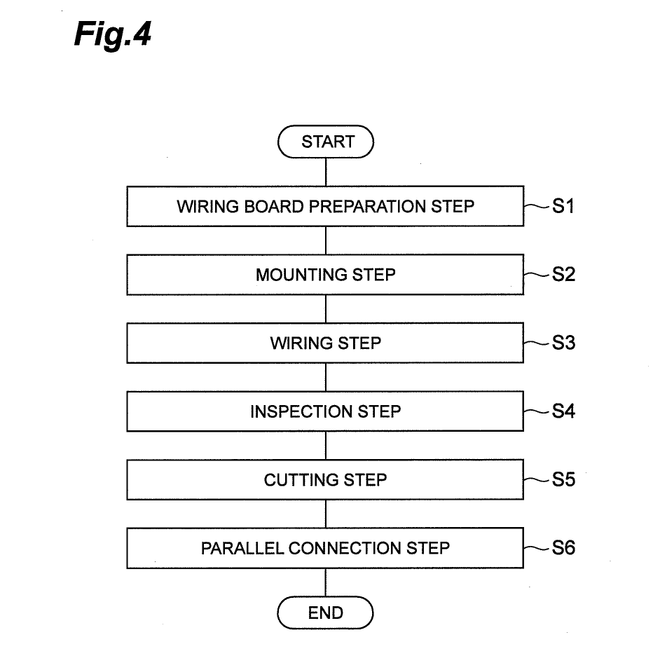

With reference to FIGS. 4 to 6, one example of manufacturing method of the semiconductor device 1 will be explained. FIG. 4 is a flowchart illustrating one example of manufacturing method of the semiconductor device 1 shown in FIG. 1.

First, the wiring board 20 in which the wiring pattern 22 is formed on the insulating substrate 21 is prepared (wiring board preparation step S1). The wiring pattern 22 may be prepared by printing it on, for example, the insulating substrate 21. In this case, the wiring board 20 is a so-called printed wiring board.

Next, the eleven semiconductor elements 10₁ to 10₁₁ are mounted on the wiring board 20 (mounting step S2). In the mounting step S2, the corresponding semiconductor elements 10₁ to 10₁₁ are die-bonded on the drain electrode regions 22A₁ to 22A₁₁ of the wiring pattern 22. Thereby, the drain terminal part 14 of the respective semiconductor elements 10₁ to 10₁₁ is electrically connected to the corresponding drain electrode region 22A₁, 22A₂, . . . , or 22A₁₁.

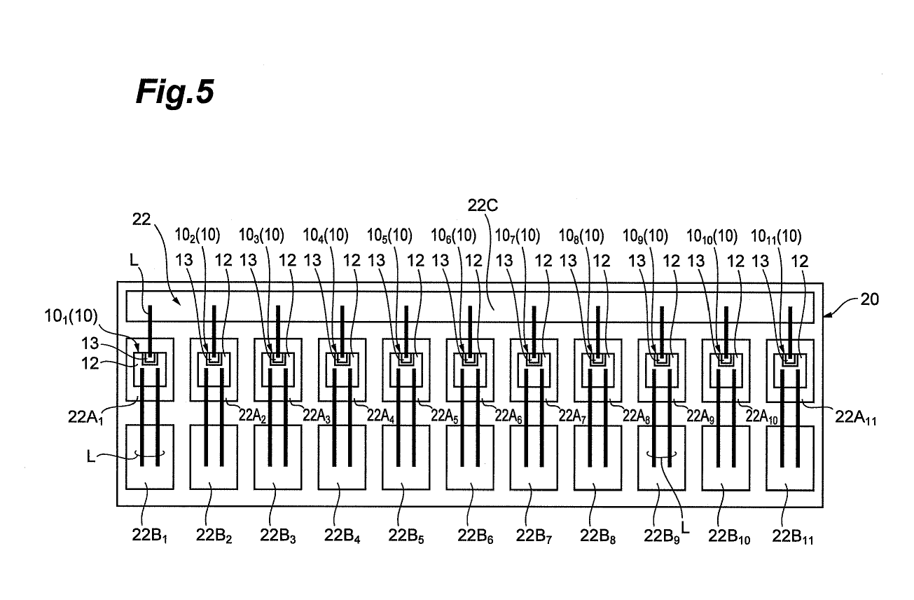

Then, the semiconductor elements 10₁ to 10₁₁ are wired on the wiring pattern 22 such that the semiconductor elements 10₁ to 10₁₁ is drivable (wiring step S3). FIG. 5 is a top view showing the wiring board 20 in which the semiconductor elements 10₁ to 10₁₁ are wired on the wiring pattern 22 in the wiring step S3. In the wiring step S3, the source terminal part 12 of the respective semiconductor elements 10₁ to 10₁₁ is wire-bonded to the corresponding source terminal region 22B₁, 22B₂, . . . , or 22B₁₁ with the conductor wire L, respectively, and the gate terminal part 13 of the respective semiconductor elements 10₁ to 10₁₁ is wire bonded to the gate electrode region 22C with the conductor wire L, respectively. Thereby, the source terminal part 12 and the gate terminal part 13 of the respective semiconductor elements 10₁ to 10₁₁ are electrically connected to the source electrode region 22B₁ to 22B₁₁ and the gate electrode region 22C, respectively. Since the drain terminal part 14 of the respective semiconductor elements 10₁ to 10₁₁ is electrically connected to the drain electrode regions 22A₁ to 22A₁₁, the wiring as shown in FIG. 5 allows the semiconductor elements 10₁ to 10₁₁ to be driven.

In this state, by driving the semiconductor elements 10₁ to 10₁₁, the semiconductor elements 10₁ to 10₁₁ are inspected (inspection step S4). Inspection can be performed by checking whether or not the semiconductor elements 10₁ to 10₁₁ normally function. Examples of such an inspection include that in which the heat generated by applying a voltage to the respective semiconductor elements 10₁ to 10₁₁ is detected. In mounting the semiconductor elements 10₁ to 10₁₁ on the wiring board 20, and wiring the semiconductor elements 10₁ to 10₁₁ to the wiring pattern 22, at least two terminals (for example, the drain terminal part 14 and the source terminal part 12) which the semiconductor elements 10₁ to 10₁₁ have may be short-circuited. If such a short-circuit is caused, application of a voltage to the semiconductor elements 10₁ to 10₁₁ will cause a current of a few milliamperes or so to flow, resulting in heat generation, and thus by detecting the heat generation, a no-good semiconductor element can be identified. The heat generation may be detected by, for example, utilizing a thermography, which outputs the temperature distribution of an object as a screen image (a picture), or an infrared microscope, or like that. In the explanation of the present embodiment, the semiconductor elements 10₆ and 10₁₁ are no-good semiconductor elements as described above.

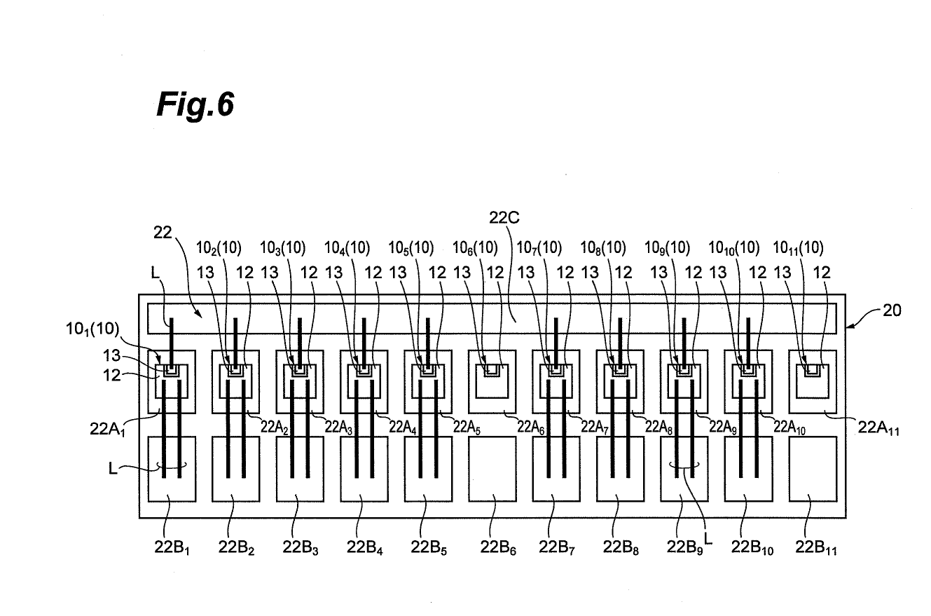

The wiring between each of the two semiconductor elements 10₆ and 10₁₁, which have been judged as no-good in the inspection step S4, and the wiring pattern 22 for driving those semiconductor elements 10₆ and 10₁₁ is cut. Specifically, the conductor wires L connecting between the source terminal parts 12 of the semiconductor element 10₆ and 10₁₁ and the source electrode regions 22B₆ and 22B₁₁ are cut, respectively, and the conductor wires L connecting between the gate terminal part 13 of the respective semiconductor elements 10₆ and 10₁₁ and the gate electrode region 22C are cut. This cutting of the conductor wire L may be performed manually, or by, for example, using a known device, such as a laser working device. In a case where a known device, such as a laser working one, is utilized, it may be integrated with a system for heat generation detection for use in the inspection as described above. FIG. 6 is a drawing showing a state in which the wiring between the respective no-good semiconductor elements 10₆ and 10₁₁, and the wiring pattern 22 is cut.

Then, the nine semiconductor elements 10₁ to 10₅ and 10₇ to 10₁₀, which have passed the inspection are electrically connected in parallel (parallel connection step S6). Specifically, to the source electrode region 22B₁₀ in correspondence to the semiconductor element 10₁₀ at extreme end of the normally functioning semiconductor elements 10₁ to 10₅ and 10₇ to 10₁₀ which are physically disposed in parallel, one end of the shunt resistor 30B is connected, while the other end of the shunt resistor 30B is connected to the source electrode region 22B₁₁. Likewise, to the drain electrode region 22A₁₀ corresponding to the semiconductor element 10₁₀, one end of the shunt resistor 30B is connected, while the other end of the shunt resistor 30B is connected to the drain electrode region 22A₁₁. Further, of the couples of adjacent source electrode regions, 22B₁ and 22B₂, 22B₂ and 22B₃, . . . , 22B₁₀ and 22B₁₁, the couples of adjacent source electrode regions other than the couple of source electrode regions 22B₁₀ and 22B₁₁, which are connected by the shunt resistor 30B, are connected with the conductor wires L. Likewise, of the adjacent drain electrode regions 22A₁ to 22A₁₁, the couples of the adjacent drain electrode regions other than the couple of the drain electrode regions 22A₁₀ and 22A₁₁ which are connected by the shunt resistor 30A are connected with the conductor wires L. Thereby, there is provided a semiconductor device in which the normally functioning semiconductor elements 10₁ to 10₅ and 10₇ to 10₁₀ are electrically connected in parallel, and in the parallel connection, the semiconductor element 10₁₀ for which the current is detected is electrically connected in parallel to the other semiconductor elements 10₁ to 10₅ and 10₇ to 10₉ through the shunt resistors 30B and 30A.

As exemplified in FIG. 2, in a case where the semiconductor elements 10₁ to 10₁₁ are molded with the resin 40, the parallel connection step S6 may be followed by mold-forming the wiring board 20 mounted with the semiconductor elements 10₁ to 10₁₁. Further, in the mode in which the measuring terminals t1 to t4 and the external connection terminals t5 to t7 are to be provided, the measuring terminals t1 to t4 and the external connection terminals t5 to t7 may be provided prior to the mold-forming. In a case where the mold-forming is not to be performed, it is preferable that the measuring terminals t1 to t4 be provided after the disposed position of the shunt resistors 30A and 30B has been established. The external connection terminals t5 to t7 may be provided in any step.

In the aforementioned semiconductor device 1, by connecting any one of the drain electrode regions 22A₁ to 22A₁₁, and any one of the source electrode regions 22B₁ to 22B₁₁ to the voltage source for supplying a voltage, and supplying the voltage, the voltage can be supplied across the source terminal parts 12 and the drain terminal parts 14 of the semiconductor elements 10₁ to 10₅, and 10₇ to 10₁₀. Further, by connecting the gate electrode region 22C to a control signal generation source which generates a control signal, and supplying the control signal, the control signal can be supplied to the gate terminal parts 13 of the semiconductor elements 10₁ to 10₅, and 10₇ to 10₁₀. As a result, in correspondence to the control signal, a current flows through the semiconductor elements 10₁ to 10₅, and 10₇ to 10₁₀. In this way, by measuring the voltage across the shunt resistor 30A or the shunt resistor 30B with the semiconductor device 1 being driven, the current flowing through the semiconductor element 10₁₀ can be detected, because the resistance value of the shunt resistor 30A or shunt resistor 30B is known. The current value thus detected can be utilized for controlling, for example, the protection circuit of the semiconductor device 1.

In the aforementioned manufacturing method of the semiconductor device 1, the cutting step S5 is implemented prior to the parallel connection step S6, however, S5 may be implemented after the parallel connection step S6.

In the semiconductor device 1, the semiconductor elements 10₁ to 10₅, and 10₇ to 10₁₀ which have been selected from the eleven semiconductor elements 10₁ to 10₁₁ by the inspection are connected in parallel through the wiring pattern 22. Therefore, even if the semiconductor element 10 is small-sized, a predetermined current capacity can be ensured as a whole of the semiconductor device 1. Further, the semiconductor element 10₁₀, which is one of the semiconductor elements 10₁ to 10₅, and 10₇ to 10₁₀ which have passed the inspection, is defined as a semiconductor element 10 for current detection, and the semiconductor element 10₁₀ is connected in parallel to the other semiconductor elements 10₁ to 10₅, and 10₇ to 10₉ through the shunt resistors 30A and 30B. With this scheme, the semiconductor device 1 detects the current flowing through a single semiconductor element 10₁₀, and therefore, even if a plurality of semiconductor elements 10 is provided in order to ensure a predetermined current capacity, the power loss due to the current detection can be reduced.

In a case where the semiconductor material forming the semiconductor element 10 is SiC, GaN or diamond, which is a so-called wideband gap semiconductor, the semiconductor device 1 can be utilized for power handling. In this case, it is required to cause a higher current to flow through the semiconductor device 1. On the other hand, being formed to contain SiC, GaN or diamond, the semiconductor element 10 is small in size, as compared to the element which is formed of Si, or the like, as the semiconductor material. Accordingly, the aforementioned scheme which, by connecting the semiconductor elements 10₁ to 10₅, and 10₇ to 10₁₀ in parallel, ensures a predetermined current capacity, while being capable of reducing the loss due to the current detection, is more advantageous in a case where the semiconductor device 1 is provided with the semiconductor elements 10 formed to contain SiC, GaN or diamond, and is utilized for power handling.

Further, the mode in which, as shown in FIGS. 1 and 2, the source electrode regions 22B₁ to 22B₁₁ which are physically separated from one another are provided on the insulating substrate 21 in correspondence to the respective semiconductor elements 10₁ to 10₁₁, and the drain electrode regions 22A₁ to 22A₁₁ which are physically separated from one another are provided on the insulating substrate 21 in correspondence to the respective semiconductor elements 10₁ to 10₁₁ allows the semiconductor elements 10₁ to 10₁₁ to be individually driven for inspecting the semiconductor elements 10₁ to 10₁₁.

In the mode including the source electrode regions 22B₁ to 22B₁₁ and the drain electrode regions 22A₁ to 22A₁₁ which are thus physically separated, in a case where, as shown in FIGS. 1 and 2, of the semiconductor elements 10₁ to 10₅, and 10₇ to 10₁₀ which are disposed in parallel and normally function, the extreme end semiconductor element 10₁₀ is connected to the shunt resistors 30A and 30B, and as described above, the adjacent source electrode regions 22B₁ to. 22B₁₁ and the adjacent drain electrode regions 22A₁ to 22A₁₁ are connected to each other with the conductor wires L, there is no need for further ensuring another wiring region for parallel connection of the semiconductor elements 10₁ to 10₅, and 10₇ to 10₁₀, and another wiring region for connection of the shunt resistors 30A and 30B, whereby the wiring board 20 can be made smaller in size. As a result, the semiconductor device 1 can be made compact.

In addition, as described in the explanation of the method of manufacturing the semiconductor device 1, the semiconductor device 1 is inspected after the eleven semiconductor elements 10₁ to 10₁₁ mounted on the wiring board 20 have been provided with a predetermined wiring, and on the basis of the result of the inspection, the wiring of the no-good semiconductor elements 10₆ and 10₁₁ is cut. Therefore, the other semiconductor elements 10₁ to 10₅, and 10₇ to 10₁₀ which have passed the inspection can be advantageously utilized.

### Second Embodiment

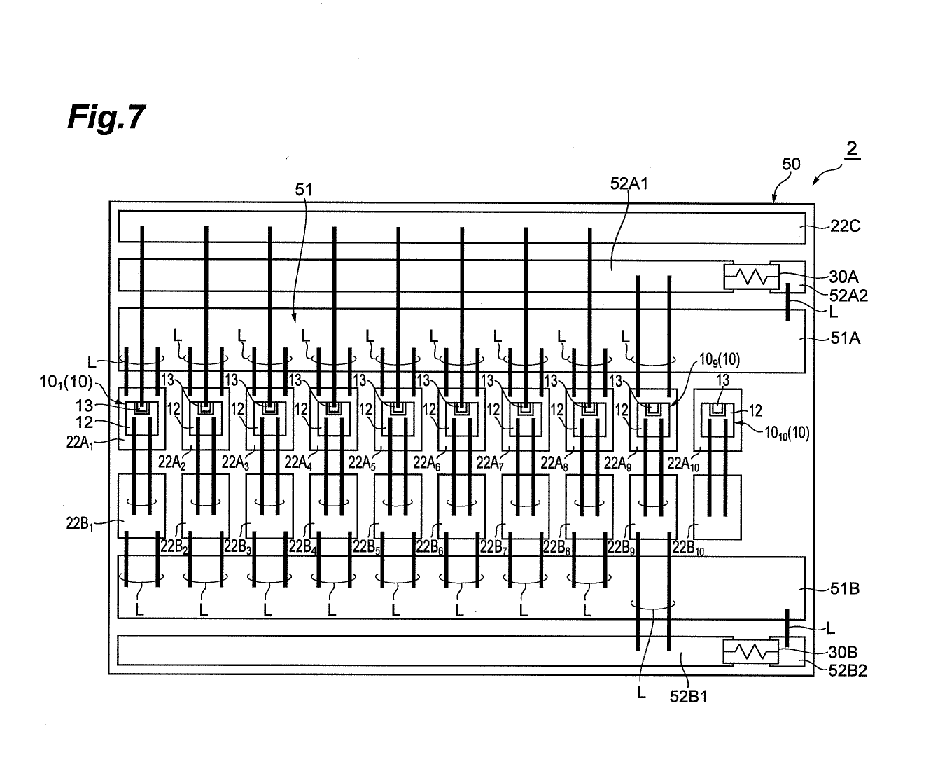

FIG. 7 is a top view illustrating the schematic configuration of a semiconductor device according to another embodiment. A semiconductor device 2 shown in FIG. 7 differs from the semiconductor device 1 in that it includes a wiring board 50 having a wiring pattern 51 in place of the wiring board 20. The configuration except for this different point is the same as the configuration of the semiconductor device 1. The configuration of the semiconductor device 2 will be explained here, the explanation being focused mainly on the different point. The semiconductor device 2 also includes N semiconductor elements 10. Hereinbelow, for convenience of explanation, the mode including ten semiconductor elements 10 as shown in FIG. 7 will be explained. The ten semiconductor elements 10 will be referred to as the semiconductor elements 10₁ to 10₁₀ as is the case with the semiconductor device 1, and for the components of the semiconductor device 2 that correspond to the semiconductor elements 10₁ to 10₁₀, the same notation will be adopted. In the semiconductor device 2, the semiconductor element 10₁₀ is a no-good semiconductor element.

The wiring pattern 51 includes a source wiring region 51B and a drain wiring region 51A for wiring, separately from the source electrode regions 22B₁ to 22B₁₀ and drain electrode regions 22A₁ to 22A₁₀ which correspond to the respective semiconductor elements 10₁ to 10₁₀. Further, the wiring pattern 51 includes a pair of shunt resistor wiring regions 52A₁ and 52A₂ for connecting a shunt resistor 30A, and a pair of shunt resistor wiring regions 52B₁ and 52B₂ for providing a shunt resistor 30B.

The source wiring region 51B and the drain wiring region 51A extend in the direction of arrangement of the ten semiconductor elements 10₁ to 10₁₀ (or, the direction of arrangement of the drain electrode regions 22A₁ to 22A₁₀). Further, each of the shunt resistor wiring regions 52A₁ and 52B₁ extends in the direction of arrangement of the semiconductor elements 10₁ to 10₁₀.

In the mode shown in FIG. 7, of the semiconductor elements 10₁ to 10₁₀, the semiconductor element 10₉ is a semiconductor element for current detection. The source electrode regions 22B₁ to 22B₈ and drain electrode regions 22A₁ to 22A₈ which correspond to the semiconductor elements 10₁ to 10₈ other than the semiconductor element 10₉ for current detection are connected to the source wiring region 51B and the drain wiring region 51A with a conductor wires L, respectively. The source electrode region 22B₉ which corresponds to the semiconductor element 10₉ for current detection is connected to the shunt resistor wiring region 52B1 extending in one direction of a pair of shunt resistor wiring regions 52B1 and 52B2, with the conductor wire L. The shunt resistor wiring region 52B2 is connected to the source wiring region 51B with the conductor wire L. Likewise, the drain electrode region 22A₉ which corresponds to the semiconductor element 10₉ for current detection is connected to the shunt resistor wiring region 52A1 extending in one direction of a pair of shunt resistor wiring regions 52A1 and 52A2, with the conductor wire L. On the other hand, the shunt resistor wiring region 52A2 is connected to the drain wiring region 51A with the conductor wire L.

The aforementioned semiconductor device 2 is manufactured in the following manner, for example. An example of manufacturing method of the semiconductor device 2 will be explained here, the explanation being focused mainly on the point different from the manufacturing method as described in the explanation of the semiconductor device 1.

First, in the wiring board preparation step Si given in FIG. 4, the wiring board 50 having the wiring pattern 51 on the insulating substrate 21 is prepared. Next, as given in FIG. 4, after the mounting step S2 having been implemented, the wiring step S3 and the inspection step S4 are implemented in this order.

Then, by implementing the cutting step S5, the wiring for driving the no-good semiconductor element 10₁₀ is cut in the wiring between the no-good semiconductor element 10₁₀ and the wiring pattern 51. Specifically, the electrical connection between the gate terminal part 13 of the semiconductor element 10₁₀ and the gate electrode region 22C is cut. Thereby, since a control signal is not input to the no-good semiconductor element 10₁₀, the no-good semiconductor element 10₁₀ will not be driven.

Thereafter, in the parallel connection step S6, the source electrode regions 22B₁ to 22B₈ which correspond to the respective semiconductor elements 10₁ to 10₈ other than the semiconductor element 10₉ for current detection of the normally functioning semiconductor elements 10₁ to 10₉ are wire-bonded to the source wiring region 51B with the conductor wires L, and the drain electrode regions 22A₁ to 22A₈ which correspond to the respective semiconductor elements 10₁ to 10₈ are wire-bonded to the drain wiring region 51A with the conductor wires L. Further, the source electrode region 22B₉ and the drain electrode region 22A₉ which correspond to the semiconductor element 10₉ are wire-bonded to the shunt resistor wiring region 52B₁ and the shunt resistor wiring region 52A1 with the conductor wires L, respectively. In addition, the shunt resistor wiring region 51A1 and the shunt resistor wiring region 51A2 are electrically connected to each other through the shunt resistor 30A, and the shunt resistor wiring region 52A2 and the drain wiring region 51A are wire-bonded to each other with the conductor wire L. Likewise, the shunt resistor wiring region 52B 1 and the shunt resistor wiring region 52B2 are electrically connected to each other through the shunt resistor 30B, and the shunt resistor wiring region 52B2 is wire-bonded to the source wiring region 51B with the conductor wire L. Thereby, the semiconductor device 2 shown in FIG. 7 is obtained.

Also with the manufacturing method of the semiconductor device 2, the cutting step S5 may be implemented after the parallel connection step S6.

In the semiconductor device 2, the semiconductor elements 10₁ to 10₉ which have been selected from the ten semiconductor element 10₁ to 10₁₀ by the inspection are connected in parallel. Therefore, even if the semiconductor element 10 is small-sized, a predetermined current capacity can be ensured as a whole of the semiconductor device 2. Further, one semiconductor element 10₉ of the semiconductor elements 10₁ to 10₉ is defined as the semiconductor element for current detection, and the semiconductor element 10₉ is connected in parallel to the other semiconductor elements 10₁ to 10₈ through the shunt resistors 30A and 30B. With this scheme, the current flowing through a single semiconductor element 10₉ is detected, and therefore, even if a plurality of semiconductor elements 10 is provided in order to ensure a predetermined current capacity, the power loss due to the current detection can be reduced.

Further, as described in the explanation of the manufacturing method of the semiconductor device 2, a plurality of semiconductor elements 10₁ to 10₁₀ is inspected, and the wiring of the no-good semiconductor element 10₁₀ is cut, whereby the other semiconductor elements 10₁ to 10₉ which have passed the inspection can be advantageously utilized. Further, in correspondence to the respective semiconductor elements 10₁ to 10₁₀, the source electrode regions 22B₁ to 22B₁₀ which are physically separated from one another and the drain electrode regions 22A₁ to 22A₁₀ which are physically separated from one another are provided on the insulating substrate 21, whereby, in inspecting the semiconductor elements 10₁ to 10₁₀, the respective semiconductor elements 10₁ to 10₁₀ can be individually inspected.

In the aforementioned one example of manufacturing method of the semiconductor device 2, connection of the shunt resistors 30A and 30B has been performed in the wiring step S3. However, in a case where the semiconductor device 2 is to be manufactured, the wiring board 50 which has been mounted with the shunt resistors 30A and 30B may be prepared in, for example, the wiring board preparation step S1. In this case, in the wiring step S3, only the wiring for the semiconductor elements 10₁ to 10₉ may be performed.

Also in the semiconductor device 2 of the present embodiment, the measuring terminals t1 to t4 and the external connection terminals t5 to t7 may be provided as in the semiconductor device 1.

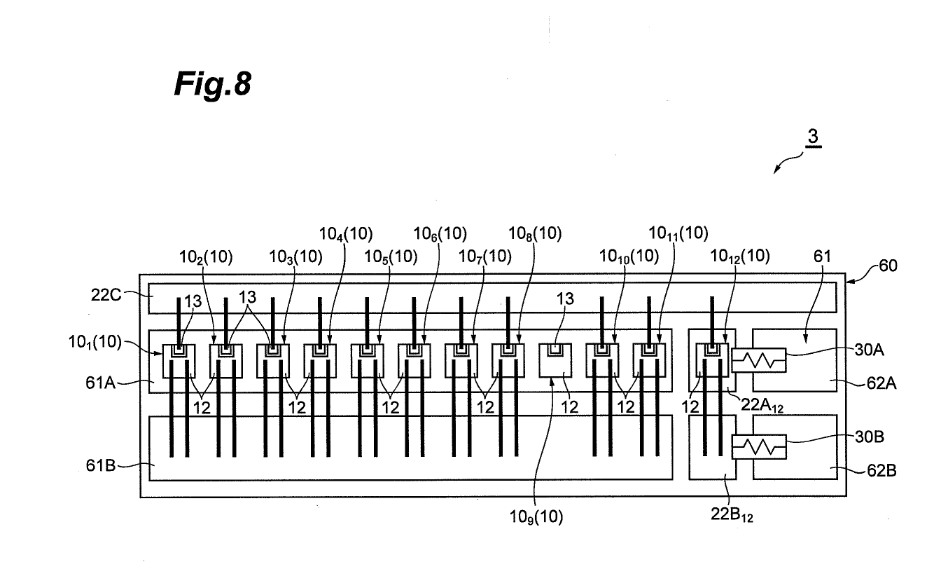

Hereinabove, the embodiments of the present invention have been explained, however, the present invention is not limited to the aforementioned embodiments. For example, a configuration, such as that of a semiconductor device 3 as shown in FIG. 8 is also possible. The semiconductor device 3 will be explained here, the explanation being focused mainly on the point of difference from the semiconductor device 1. For convenience of explanation, as is the case with the semiconductor device 1, the semiconductor device 3 has twelve semiconductor elements 10 and the respective semiconductor elements 10 are referred to as the semiconductor elements 10₁ to 10₁₂, as shown in the figure. In addition, also for the components of the semiconductor device 3 which correspond to the semiconductor elements 10₁ to 10₁₂, the same notation will be adopted. In the semiconductor device 3, the semiconductor element 10₉ is a no-good semiconductor element.

The semiconductor device 3 shown in FIG. 8 differs in configuration from the semiconductor device 1 in that the former includes a wiring board 60 having a wiring pattern 61. The wiring pattern 61 has single electrode regions 61A and 61B each of which extends in one direction for the semiconductor elements 10₁ to 10₁₁ other than the semiconductor element 10₁₂ to which the shunt resistors 30A and 30B are connected. In addition, the wiring pattern 61 has a shunt resistor connection regions 62A and 62B which are connected to the drain electrode region 22A₁₂ and the source electrode region 22B₁₂ of the semiconductor element 10₁₂ through the shunt resistors 30A and 30B, respectively. For such a semiconductor device 3, a wiring board on which there is formed a wiring pattern having an electrode region in which the electrode region 61A and the drain electrode region 22A₁₂ are physically connected, and the electrode region 61B and the source electrode region 22B₁₂ are physically connected is prepared in, for example, the wiring board preparation step S1. Then, utilizing the wiring board, the respective manufacturing steps given in FIG. 4 are sequentially implemented and in the cutting step S5 after the inspection step S4, cutting of the wiring may be performed while the drain electrode region 22A₁₂ and the source electrode region 22B₁₂ being separated from the aforementioned electrode regions on the wiring board which have been prepared in the wiring board preparation step S1. Note that, a wiring board 60 having a wiring pattern 61 in which the drain electrode region 22A₁₂ and the source electrode region 22B₁₂, the semiconductor element 10₁₂ being disposed therein, have been previously separated from the electrode regions 61A and 61B may be prepared, and the wiring board 60 may be utilized for manufacturing the semiconductor device 3.

In addition, the semiconductor element 10 has been defined to be an MOSFET for explanation, however, the semiconductor element 10 may be another type of transistor, or a diode. The wiring pattern which the wiring board has may be any wiring pattern, provided that it is in correspondence to the type of the semiconductor element. The semiconductor material which forms the semiconductor element 10 is not limited to SiC, GaN or diamond, and may be Si. Further, the semiconductor element 10 for current detection is not limited to a single, and m semiconductor elements (where m is equal to or greater than 1 but less than M) of M semiconductor elements which have been selected from N semiconductor elements may be substituted therefor. The case where m is equal to or greater than 2, and the m semiconductor elements are connected in parallel to the other semiconductor elements of the M semiconductor elements through the shunt resistor will be explained here. In this case, the m semiconductor elements are connected in parallel to form a first parallel connection group; the (M-m) semiconductor elements are connected in parallel to form a second parallel connection group; and the first and second parallel connection groups may be connected through the shunt resistors such that the M semiconductor elements are connected in parallel through the shunt resistors. From the viewpoint of reducing the power loss due to the current detection, it is preferable that the number of semiconductor elements 10 for current detection be smaller. For example, it is preferable that m be equal to or less than M/2, and more preferable that m be equal to M/3. Further, as described in the embodiment, it is the most preferable that m is equal to 1.

Further, the M semiconductor elements which are connected in parallel has been defined as the semiconductor elements which have been judged as good by the inspection. However, the M semiconductor elements may be those which have been selected from the N semiconductor elements. For example, in a case where the (N-M) semiconductor elements have been previously mounted as a spare, the M semiconductor elements may be connected in parallel without performing the inspection. Like this, in a case where the inspection is not performed, there is no need for implementing the inspection step S4 and the cutting step S5 in the manufacturing process given in FIG. 4. Further, the wiring which corresponds to the wiring step S3 may be performed in the parallel connection step S6.

Furthermore, the mode in which the shunt resistors 30A and 30B are provided has been explained, however, either one of the shunt resistor 30A and shunt resistor 30B may be provided. In addition, the current detection part is not limited to a shunt resistor, and may be any component which allows the current flowing through the semiconductor element to be detected.

In addition, in the above-described embodiments, the number of semiconductor elements to be mounted on the wiring board has been specifically exemplified for explanation, however, the number of plural semiconductor elements to be mounted on the wiring board is not limited to the number which has been exemplified.

What is claimed is:

1. A semiconductor device, comprising:
a wiring board having a wiring pattern;
N semiconductor elements (where N denotes a natural number equal to or greater than 2) mounted on the wiring board; and
a current detection part for detecting a current flowing through m semiconductor elements (where m denotes a natural number equal to or greater than 1 but less than M) of M semiconductor elements (where M denotes a natural number equal to or greater than 1 but equal to or less than N) mounted on the wiring board and selected from the N semiconductor elements, wherein
the M semiconductor elements are electrically connected in parallel through the wiring pattern, and
the m semiconductor elements are electrically connected in parallel to the other semiconductor elements of the M semiconductor elements through the current detection part.

2. The semiconductor device according to claim 1, wherein
the M semiconductor elements are semiconductor elements which, after the N semiconductor elements having been wired on the wiring pattern such that each of the semiconductor elements is drivable, have been judged as good in an inspection for judging whether the semiconductor elements are good or no-good, and
the (N-M) semiconductor elements other than the M semiconductor elements of the N semiconductor elements are electrically separated from the M semiconductor elements.

3. The semiconductor device according to claim 1, wherein the m is 1.

4. The semiconductor device according to claim 3, wherein
the semiconductor element has first and second main terminals, and a control terminal which receives a control signal for controlling the conduction between the first and second main terminals,
the N semiconductor elements are disposed in parallel, wherein
the wiring pattern has:
N first wiring regions which are separated from each other and provided in correspondence to the first main terminal of each of the N semiconductor elements;
N second wiring regions which are separated from each other and provided in correspondence to the second main terminal of each of the N semiconductor elements; and
a third wiring region which is provided for the control terminals of the N semiconductor elements, wherein
the first and second main terminals and the control terminals of the M semiconductor elements are electrically connected to the corresponding first to third wiring regions, respectively,
a semiconductor element for current detection as the semiconductor element the current for which is detected by the current detection part is a semiconductor element located at the extreme end of the M semiconductor elements which are disposed in parallel,
at least one of a couple of the first wiring region corresponding to the semiconductor element for current detection and the first wiring region corresponding to the semiconductor element adjacent to the semiconductor element for current detection, and a couple of the second wiring region corresponding to the semiconductor element for current detection and the second wiring region corresponding to the semiconductor element adjacent to the semiconductor element for current detection are connected through the semiconductor element for current detection,
of the couples of the first wiring regions corresponding to the semiconductor elements adjacent to each other in the N first wiring regions and of the couples of the second wiring regions corresponding to the semiconductor elements adjacent to each other in the N second wiring regions, the couples other than the couple connected by the current detection part are connected with a conductor wire, and
the (N-M) semiconductor elements other than the M semiconductor elements of the N semiconductor elements are electrically separated from the M semiconductor elements.

5. The semiconductor device according to claim 1, wherein a semiconductor material forming the semiconductor element is SiC, GaN or diamond.

6. A manufacturing method of semiconductor device, comprising the steps of:
mounting N semiconductor elements (where N denotes a natural number equal to or greater than 2) on a wiring board having a wiring pattern; and
electrically connecting of the M semiconductor elements (where M denotes a natural number equal to or greater than 1 but equal to or less than N) selected from the N semiconductor elements in parallel through the wiring pattern, wherein
in the parallel connection step above, the m semiconductor elements (where m denotes a natural number equal to or greater than 1 but less than M) of the M semiconductor elements are connected in parallel to the other semiconductor elements of the M semiconductor elements through a current detection part for detecting a current flowing through the m semiconductor elements.

7. The manufacturing method of semiconductor device according to claim 6, further comprising the steps of
drivably wiring of the N semiconductor elements mounted in the mounting step on the wiring pattern;
inspecting whether the semiconductor elements are good or no-good by driving the N semiconductor elements; and
cutting at least a part of wiring between the (N-M) semiconductor elements and the wiring pattern such that the (N-M) semiconductor elements which have been judged as no-good in the inspection will not be driven, wherein
in the parallel connection step above, the M semiconductor elements selected from the N semiconductor elements as semiconductor elements which have been judged as good in the inspection are electrically connected in parallel through the wiring pattern.

8. The manufacturing method of semiconductor device according to claim 6, wherein the m is 1.

9. The manufacturing method of semiconductor device according to claim 6, further comprising the steps of:
drivably wiring the N semiconductor elements mounted on the wiring pattern in the mounting step above, respectively;
inspecting whether the semiconductor elements are good or no-good by driving the N semiconductor elements and
cutting at least a part of wiring between the (N-M) semiconductor elements and the wiring pattern such that the (N-M) semiconductor elements which have been judged as no-good in the inspection will not be driven, wherein
in the mounting step above, the N semiconductor elements are physically disposed in parallel to be mounted on the wiring board,
the m is 1,
a semiconductor element for current detection as the semiconductor element the current for which is detected by the current detection part is a semiconductor element located at the extreme end of the M semiconductor elements, and
the semiconductor element has first and second main terminals, and a control terminal which receives a control signal for controlling the conduction between the first and second main terminals, wherein
the wiring pattern has:
N first wiring regions which are separated from each other and provided in correspondence to the first main terminal of each of the N semiconductor elements;
N second wiring regions which are separated from each other and provided in correspondence to the second main terminal of each of the N semiconductor elements; and
a third wiring region to which the control terminals of the N semiconductor elements are electrically connected, wherein
in the wiring step above, the first and second main terminals and the control terminals of the N semiconductor elements are electrically connected to the corresponding first to third wiring regions, respectively,
in the cutting step above, electrical connection between at least one terminal of the first and second main terminals of the (N-M) semiconductor elements and the corresponding first and second wiring regions is cut, and
in the parallel connection step above, at least one of a couple of the first wiring region corresponding to the semiconductor element for current detection and the first wiring region corresponding to the semiconductor element adjacent to the semiconductor element for current detection, and a couple of the second wiring region corresponding to the semiconductor element for current detection and the second wiring region corresponding to the semiconductor element adjacent to the semiconductor element for current detection is connected through the semiconductor element for current detection, and
of the couples of the first wiring regions corresponding to the semiconductor elements adjacent to each other in the N first wiring regions and of the couples of the second wiring regions corresponding to the semiconductor elements adjacent to each other in the N second wiring regions, the couples other than the couple connected by the current detection part are connected with a conductor wire.
